(19) United States
(12) Patent Application Publication
(10) Pub. No.: US 2026/0304807 A1
(43) Pub. Date: Oct. 1, 2026

(54) BIPOLAR JUNCTION TRANSISTOR CO-INTEGRATED WITH NANOSHEET TRANSISTOR

(71) Applicant: INTERNATIONAL BUSINESS MACHINES CORPORATION, ARMONK, NY (US)

(72) Inventors: Anthony I-Chih Chou, Guilderland, NY (US); Robert Gauthier, Williston, VT (US); Reinaldo Vega, Mahopac, NY (US); Christopher D. Sheraw, Altamont, NY (US); Jun Liu, Clifton Park, NY (US); Keisuke Motoki, Delmar, NY (US); Mahender Kumar, Clifton Park, NY (US); Anton Tokranov, Halfmoon, NY (US); Pial Mirdha, Clifton Park, NY (US)

(21) Appl. No.: 19/096,589

(22) Filed: Mar. 31, 2025

(51) Int. Cl. H10D 10/40; H10D 10/01; H10D 64/01; H10D 64/62; H10D 84/01; H10D 84/03; H10D 84/60

(52) U.S. Cl. CPC H10D 10/40; H10D 10/051; H10D 64/017; H10D 64/62; H10D 84/0109; H10D 84/641; H10D 84/038

(57) ABSTRACT

A semiconductor device includes a vertical bipolar junction device, having a collector, a base over the collector, an emitter over the base, one or more source/drain region/dummy and dummy gate alternatively and laterally extended over the emitter, and a contact over source/drain regions of the one or more source/drain region/dummy gate.

### BACKGROUND

### Technical Field

The present disclosure generally relates to semiconductors, and more particularly, to semiconductors with nanosheet transistors and vertical bipolar junction transistor structure, and methods of creation thereof.

### Description of Related Art

The continuous miniaturization of transistors and their increasing density on chips are hallmark innovations in the semiconductor industry, closely following Moore's Law. This trend has enabled transistors to shrink to nanometer scales, allowing millions, and even billions, to be integrated onto a single chip. This advancement significantly boosts computational power and energy efficiency. The evolution towards system-on-chip architectures further enhances these capabilities by integrating various functionalities, such as processing and sensing, into a single chip.

### SUMMARY

According to an embodiment, a semiconductor device includes a vertical bipolar junction device, having a collector, a base over the collector, an emitter over the base, one or more source/drain region and dummy gate alternatively and laterally extended over the emitter; and a contact over source/drain regions of the one or more source/drain region and dummy gate.

In one embodiment, the emitter, the one or more alternating source/drain region/dummy gate, and the contact over each source/drain regions of the one or more alternating source/drain region/dummy gate form an ohmic contact.

In one embodiment, the emitter, the base and the collector are doped with an N-type dopant or a P-type dopant, wherein a concentration of a dopant of the emitter is higher than a concentration of a dopant of the collector and a concentration of a dopant of the base.

In one embodiment, the dopant of the emitter is at least one of: B, BF2, or a P-type dopant.

In one embodiment, the bipolar junction device is a P-type-/N-type/P-type device.

In one embodiment, the semiconductor device includes a plurality of P-type field-effect transistors (PFET) dummy gates over the emitter.

In one embodiment, the semiconductor device includes a plurality of N-type field-effect transistors (NFET) dummy gates over the base.

In one embodiment, the semiconductor device includes a plurality of P-type field-effect transistors (PFET) dummy gates over the collector.

According to an embodiment, a method of fabricating a semiconductor device includes forming a vertical bipolar junction device, including forming a collector, forming a base over the collector, forming an emitter over the base, forming one or more source/drain region and dummy gate alternatively and laterally extended over the emitter; and forming a contact over source/drain regions of the one or more source/drain region and dummy gate.

In one embodiment, method includes forming an ohmic contact by the emitter, the one or more alternating source/drain region/dummy gate, and the contact over each source/drain regions of the one or more alternating source/drain region/dummy gate form.

In one embodiment, method includes doping the emitter, the base and the collector with an N-type dopant or a P-type dopant, wherein a concentration of a dopant of the emitter is higher than a concentration of a dopant of the collector and a concentration of a dopant of the base.

In one embodiment, the dopant of the emitter is at least one of: B, BF2, or a P-type dopant.

In one embodiment, the bipolar junction device is a P-type-/N-type/P-type device.

In one embodiment, method includes forming a plurality of P-type field-effect transistors (PFET) dummy gates over the emitter.

In one embodiment, method includes forming a plurality of N-type field-effect transistors (NFET) dummy gates over the base.

In one embodiment, method includes forming a plurality of P-type field-effect transistors (PFET) dummy gates over the collector.

According to an embodiment, a semiconductor device includes a vertical bipolar junction device, having a collector, a base over the collector; and an emitter over the base. The emitter, the base and the collector are doped with an N-type dopant or a P-type dopant, and a concentration of a dopant of the emitter is higher than a concentration of a dopant of the collector and a concentration of a dopant of the base

In one embodiment, the semiconductor device includes one or more alternating source/drain region/dummy gate laterally extended over the emitter, and a contact over each source/drain regions of the one or more alternating source/drain region/dummy gate.

In one embodiment, the emitter, the one or more alternating source/drain region/dummy gate, and the contact over each source/drain regions of the one or more alternating source/drain region/dummy gate form an ohmic contact.

In one embodiment, the semiconductor device includes a plurality of P-type field-effect transistors (PFET) dummy gates over the emitter, a plurality of N-type field-effect transistors (NFET) dummy gates over the base, and a plurality of P-type field-effect transistors (PFET) dummy gates over the collector.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIGS. 1A-1B illustrate conventional bipolar junctions with P+emitter implant.

FIGS. 2A-2B illustrate a semiconductor device, in accordance with an embodiment.

FIG. 3 illustrates a semiconductor device after the formation of the substrate, in accordance with some embodiments.

FIG. 4 illustrates a semiconductor device after the formation of the well implants, in accordance with some embodiments.

FIG. 5 illustrates a semiconductor device after the formation of base, in accordance with some embodiments.

FIG. 6 illustrates a semiconductor device after formation of the emitter, in accordance with some embodiments.

FIG. 7 illustrates a semiconductor device after the removal of the organic planarization layer, in accordance with some embodiments.

FIG. 8 illustrates a semiconductor device after the formation of the silicon and silicon germanium layers, in accordance with some embodiments.

FIG. 9 illustrates a semiconductor device after the formation of the shallow trench isolation, in accordance with some embodiments.

FIG. 10 illustrates a semiconductor device after formation of dummy gates, in accordance with some embodiments.

FIG. 11 illustrates a semiconductor device after formation of the spacer, in accordance with some embodiments.

FIG. 12 illustrates a semiconductor device after formation of the nanosheet recesses, in accordance with some embodiments.

FIG. 13 illustrates a semiconductor device after formation of the doped regions and the inner spacer, in accordance with some embodiments.

FIG. 14 illustrates a semiconductor device after removal of the gate hard mask, in accordance with some embodiments.

FIG. 15 illustrates a semiconductor device after channel release, in accordance with some embodiments.

FIG. 16 illustrates a semiconductor device after the replacement of gate with metal, in accordance with some embodiments.

FIG. 17 illustrates a block diagram of a method for forming the semiconductor device, in accordance with an embodiment.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or active changes may be made without departing from the spirit and scope defined by the claims. The description of the embodiments is not limiting. In particular, elements of the embodiments described hereinafter may be combined with elements of different embodiments.

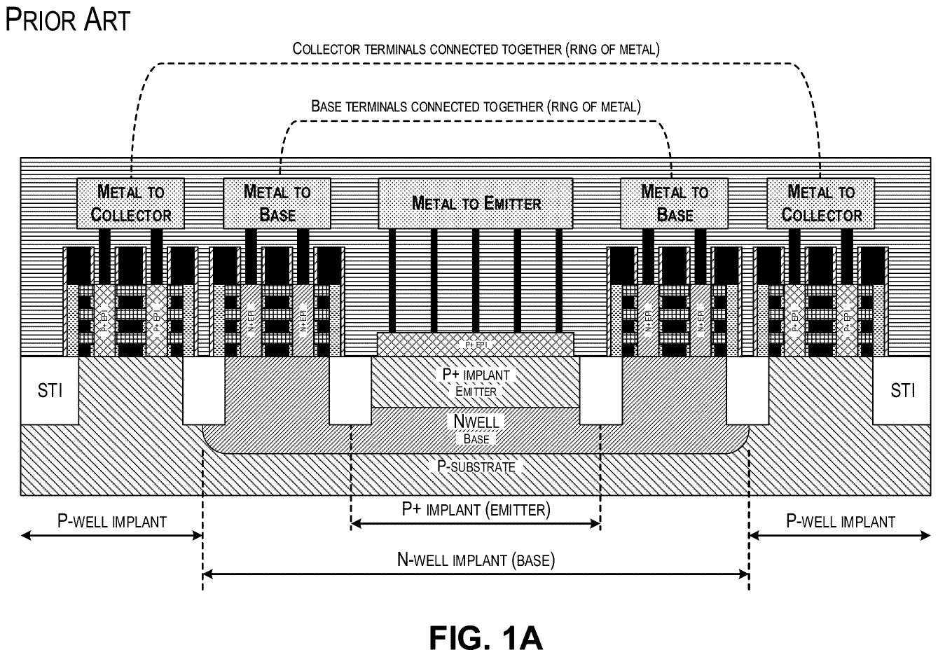

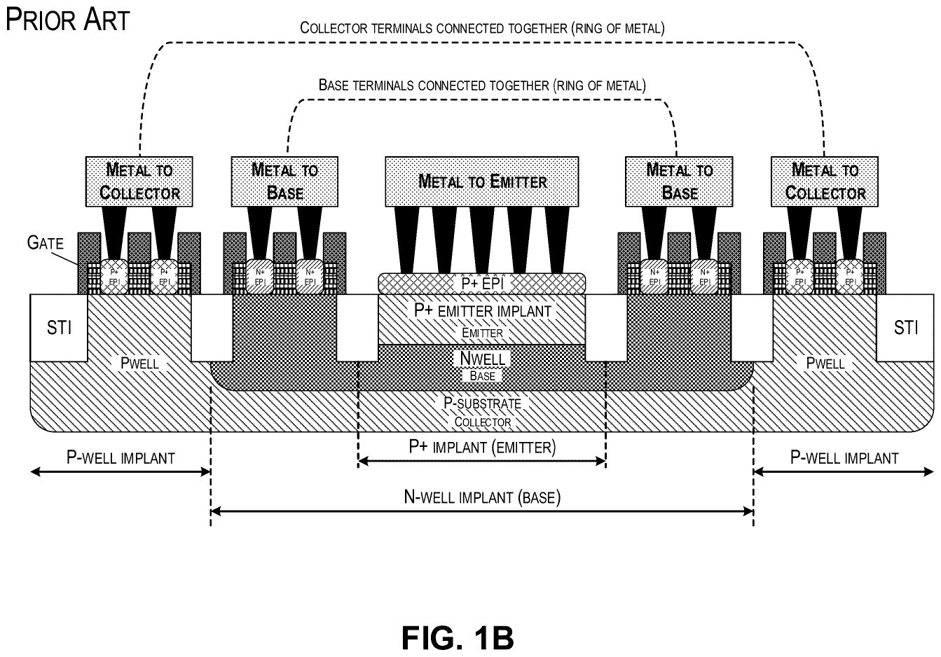

Traditionally, semiconductor devices with doped epitaxial regions, Epi, are formed on active region pads or plates without the presence of a gate electrode. “Epi” refers to epitaxially grown semiconductor material that is deposited onto the wafer to create regions with specific electrical properties. This process involves growing a crystalline layer on a substrate, maintaining the same crystal orientation, which is salient for high-quality device fabrication. The doped regions in the epitaxial layer serve as components of the transistor, such as the emitter in a bipolar junction transistor (BJT). FIGS. 1A-1B illustrate conventional BJT with P+ emitter implant including a collector, a base, an emitter, shallow trench isolation, STI, gate regions, source/drain, S/D, and contacts.

The emitter is formed by introducing a high concentration of P-type dopants into the emitter region to create a heavily doped P+area. This implantation can occur either before or after the formation of the gate electrode. Performing the doped emitter implant before gate formation is advantageous because it avoids implanting through non-uniform topography created by existing gate structures. Implanting through uneven surfaces can lead to variations in dopant concentration and depth, which can adversely affect device performance and reliability.

The P+ emitter implantation is performed pre-polycrystalline silicon (poly-Si) contacts (PC) or well formation to ensure a uniform implant profile. By conducting the implant before these steps, the process avoids the complications associated with implanting through uneven surfaces. The emitter epitaxial area, the emitter, is maximized, which leads to a lower vertical resistance in the emitter region. Vertical resistance is a measure of the opposition to current flow in the direction perpendicular to the wafer surface. A larger emitter area provides a greater cross-sectional area for current flow, thereby reducing resistance and improving the efficiency of carrier injection from the emitter to the base in a BJT.

However, the epitaxial layer height in the conventional semiconductor devices differs from that of nanosheet epitaxial layers, leading to challenges in forming electrical contacts. Nanosheet transistors utilize extremely thin semiconductor layers as channels, and the epitaxial growth conditions for these structures differ from those used in traditional devices. The difference in epitaxial heights creates difficulties in aligning and connecting contacts reliably, which is essential for proper device operation.

Additionally, a low density of polycrystalline silicon or polysilicon base regions leads to challenges in planarization. Planarization is the process of smoothing the wafer surface to create a uniform flatness necessary for subsequent lithography and layer deposition steps. A low density of these features can result in uneven surfaces, making it difficult to achieve the required planarity. This lack of planarity can cause defects in the photolithography process, leading to device failures or reduced yields.

To address these challenges and other considerations, a vertical bipolar junction transistor (BJT) with an implanted emitter region containing nanosheet channels is disclosed. This device is co-integrated with a nanosheet transistor, allowing for advanced functionality and compatibility with modern semiconductor technologies. The nanosheet channels in the vertical BJT provide enhanced electrostatic control over the channel, improving device performance and scalability. In the disclosed semiconductor device, standard epitaxial growth is performed on the nanosheet structures, which include dummy gates. Dummy gates can be placeholder gate structures used during fabrication to facilitate certain processes, such as chemical mechanical polishing (CMP), and can be later replaced with the actual gate material. The use of standard epitaxial processes ensures compatibility with existing fabrication techniques and maintains consistency in epitaxial layer height, which helps mitigate contact formation challenges.

The P+ emitter implant can be formed before the gate formation during the well formation stage. By implanting the emitter region pre-gate, the process avoids implanting through non-uniform topography that would be present if the gates were already formed. This approach ensures a uniform dopant distribution in the emitter region, which is critical for device performance and reliability. In this design, the epitaxial layer height can be the same as that of a standard nanosheet field-effect transistor (FET). Matching the epitaxial heights simplifies the fabrication process and reduces complexities associated with differing layer thicknesses. It also aids in achieving uniform planarization and improves the integration of the vertical BJT with the nanosheet FET.

The gate density in this semiconductor device is similar to that of a standard FET. Gate density refers to the number of gate structures per unit area on the chip. Maintaining a similar gate density ensures that the device architecture remains compatible with existing fabrication processes and that the planarization challenges are manageable. However, the emitter epitaxial area is smaller in this design, which results in higher vertical resistance in the emitter region. A smaller emitter area reduces the cross-sectional area available for current flow, increasing resistance. This higher vertical resistance can impact the efficiency of carrier injection and overall device performance. To compensate for this, adjustments in doping concentration or modifications to the device dimensions may be necessary to optimize performance within the constraints of the fabrication process.

Accordingly, the teachings herein provide methods and systems of vertical BJT with an implanted emitter region containing nanosheet channels. The techniques described herein may be implemented in a number of ways. Example implementations are provided below with reference to the following figures.

### Example Semiconductor Device with Nanosheet Transistors and Vertical Bipolar Junction Structure

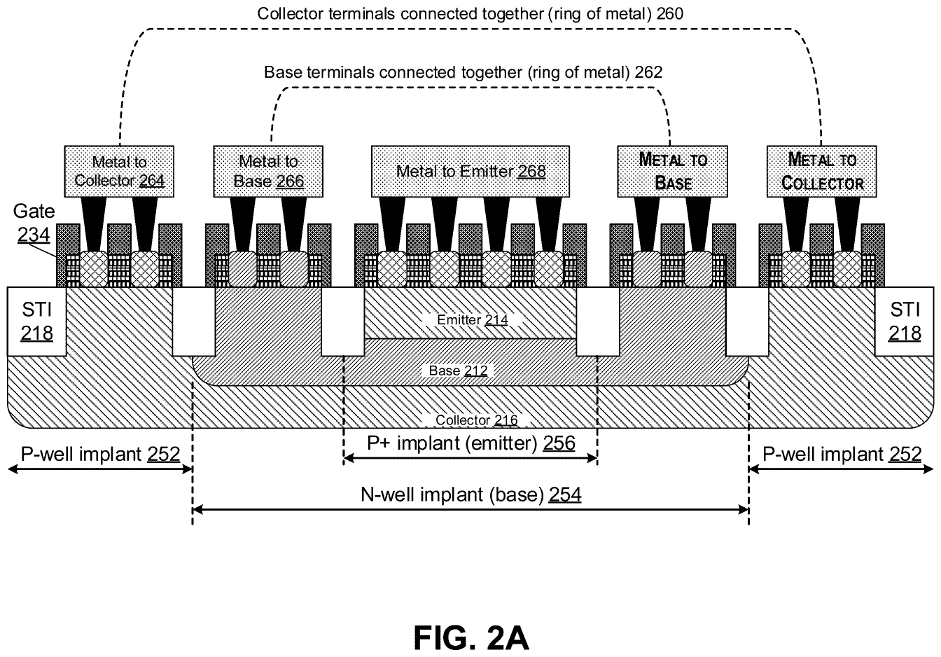

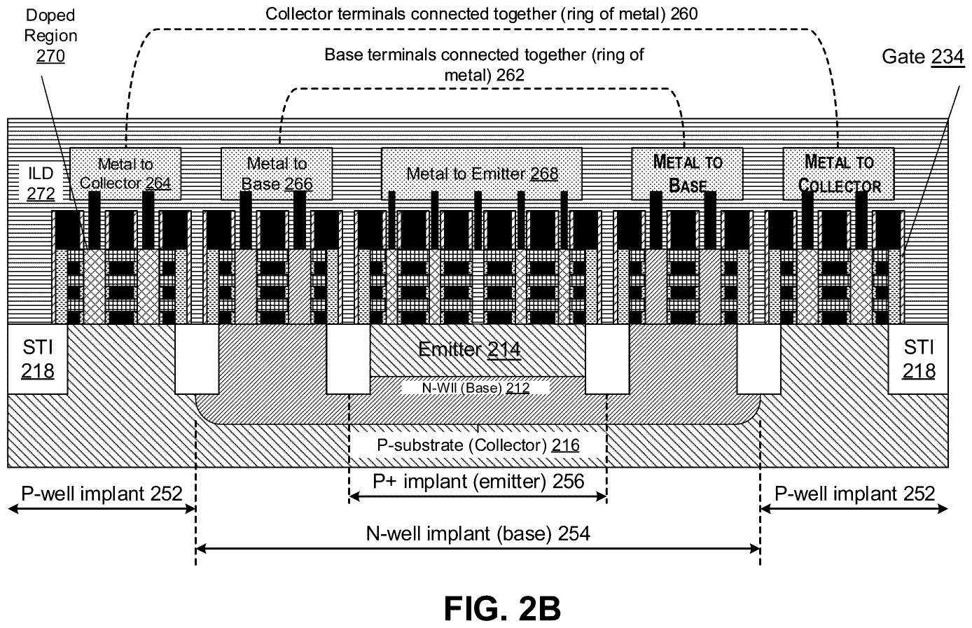

Reference now is made to FIGS. 2A-2B, which are simplified cross-section views of a semiconductor device, consistent with an illustrative embodiment. The semiconductor device can include a base 212, an emitter 214, a collector 216, shallow trench isolation, STI 218, gates 234, a P-well implants 252, and doped regions 270. The area of the emitter is shown as P+implant (Emitter) 256, and the area of the base is shown as N-well implant (base) 254. The semiconductor device can include collector terminals connected together (ring of metal) 260, base terminals connected together (ring of metal) 262, metal to collector 264, metal to base 266, metal to emitter 268, and interlayer dielectric, ILD 272.

The semiconductor device can be a vertical bipolar junction transistor (BJT), which is a type of transistor where current flows vertically through the device layers rather than horizontally. In this structure, the semiconductor device includes the collector 216, which is one of the primary regions of a BJT. The collector 216 can be the region that collects carriers (either electrons or holes) that have traversed the base 212 and is located at the bottom of the semiconductor device in a vertical configuration. The collector 216 can be a doped substrate.

Above the collector 216, is the base 212, a thin, lightly doped region that separates the emitter 214 from the collector 216. The base 212 controls the flow of carriers between the collector 216 and the emitter 214. In some embodiments, the thickness and doping level of the base 212 are so performed to allow carriers injected from the emitter 214 to pass through efficiently while still providing control over the transistor's operation. The base 212 can be a doped region, e.g., an N-well.

Over the base 212 lies the emitter 214, which can be heavily doped compared to the base 212 and the collector 216. The emitter's function can be to inject carriers into the base 212. The heavy doping ensures a high concentration of charge carriers (electrons in N-type material or holes in P-type material), which facilitates efficient injection and contributes to the transistor's amplification properties.

Extending laterally over the emitter 214 can be doped regions 270 and gates 234. The doped regions 270 can be source/drain regions which are the components where carriers enter (source) and exit (drain) the transistor channel. In some embodiments, the source/drain regions are positioned over the emitter 214 to form additional transistor structures or to facilitate connections. The gates 234 are placeholder gate structures used during fabrication to define the transistor's gate regions to assist in various processing steps, such as alignment and planarization.

Contact can be formed over each of the source/drain region. Contacts are conductive interfaces, made of metals such as aluminum or copper, that provide electrical connections between the semiconductor device and external circuitry. Contacts can allow for the flow of electrical signals into and out of the device. It should be noted that, a source/drain region can be a source region or a drain region. For the sake of simplicity, the term source/drain region is used herein to include the source region or drain region.

The gates 234 can be P-type field-effect transistor (PFET) dummy gates over the emitter 214. A PFET is a type of transistor where the majority charge carriers are holes, and operates with P-type semiconductor material. The gates 234 over the emitter 214 serve as placeholders for the PFET gate structures during fabrication.

Over the base 212, a plurality of N-type field-effect transistor (NFET) dummy gates can be located. An NFET is a transistor where electrons are the majority carriers, using N-type semiconductor material. The NFET dummy gates can be used to form NFET structures, integrating both types of transistors within the device.

Additionally, there are PFET dummy gates over the collector. This arrangement allows the device to incorporate both PFET and NFET structures in conjunction with the vertical BJT, enabling complex circuit functionalities and facilitating complementary metal-oxide-semiconductor (CMOS) technology, which uses both types of transistors to optimize performance and power efficiency.

In some embodiments, the emitter 214, the doped regions 270 and gates 234, and the contacts can form an ohmic contact. An ohmic contact is an electrical junction between a metal and a semiconductor that allows current to flow freely in both directions without significant resistance and rectification. The ohmic contact can ensure that the interface does not impede the flow of carriers, which could degrade the device's performance.

The emitter 214, the base 212, and the collector 216 can be doped with either N-type or P-type dopants, which are impurities added to the semiconductor material to modify its electrical properties. N-type doping introduces extra electrons (negative charge carriers) using elements such as phosphorus or arsenic, while P-type doping introduces holes (positive charge carriers) using elements such as boron. In some embodiments, the concentration of dopant in the emitter 214 is higher than that in the base 212 and the collector 216. The higher doping concentration in the emitter 214 can ensure efficient injection of carriers into the base 212, which is salient for the transistor's amplification capabilities.

The dopant used in the emitter 214 can be boron (B), boron difluoride (BF₂), or another P-type dopant. Boron is a common P-type dopant due to its ability to create holes in the silicon lattice by accepting electrons. Boron difluoride is often used in ion implantation processes because it allows for better control over the doping profile.

The semiconductor device can be a bipolar junction transistor, and can be configured as a P-type/N-type/P-type (PNP) device. In this configuration, the emitter 214 and the collector 216 can be doped with P-type material, and the base 212 can be doped with N-type material. In a PNP transistor, holes are the majority carriers in the emitter and collector, and electrons are the majority carriers in the base. The PNP configuration allows current to flow from the emitter to the collector when a suitable voltage is applied to the base, controlling the transistor's operation.

By integrating PFET and NFET dummy gates over the emitter 214, base 212, and collector 216, the semiconductor device can combine the functionalities of bipolar transistors and field-effect transistors within a single structure. Such an integration can enable advanced circuit designs that leverage the high-speed switching of FETs and the high current density and amplification properties of BJTs, resulting in a versatile and efficient semiconductor device suitable for complex electronic applications.

The STI 218 can electrically isolate different components by filling the trenches with an insulating material, such as silicon dioxide. The STI 218 can prevent electrical interference and crosstalk between adjacent devices, ensuring that each component operates independently without affecting its neighbors.

In some embodiments, the contacts have the same depth as those in a regular FET. Contacts are conductive interfaces that connect semiconductor regions—such as the source, drain, or emitter—to the metal interconnect layers in an integrated circuit. Having contacts of the same depth means that the vertical distance from the top surface of the semiconductor to the point where the contact interfaces with the doped region is consistent across different devices on the chip. Such a uniformity can simplify the fabrication process because the same etching and deposition steps can be applied uniformly across the wafer, reducing complexity and potential sources of error. The uniformity further improves planarization efficiency, as consistent contact depths facilitate achieving a flat surface across the wafer, which is critical for subsequent lithography steps. Additionally, uniform contact depths contribute to consistent electrical characteristics, such as resistance and capacitance, across different devices, which is salient for reliable circuit operation, especially in high-speed or analog applications where variations can significantly impact performance.

### Example Fabrication of Semiconductor Device with Nanosheet Transistors and Vertical Bipolar Junction

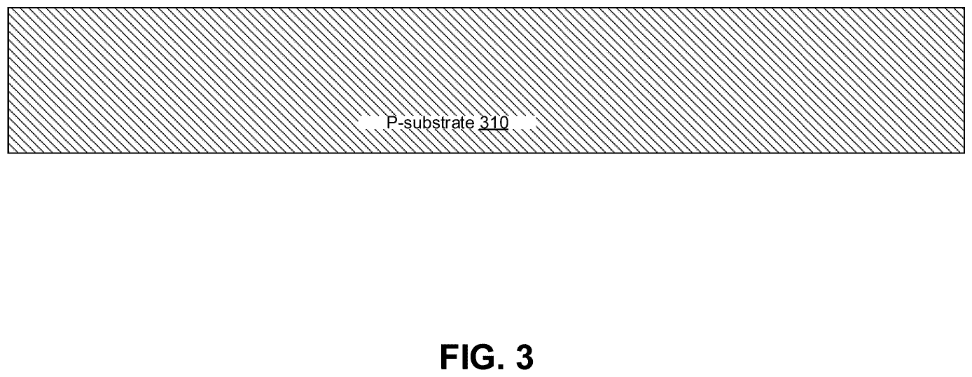

With the foregoing description of an example semiconductor device, it may be helpful to discuss an example process of manufacturing the same. To that end, FIGS. 3-18 illustrate various acts in the manufacture of a semiconductor device, consistent with illustrative embodiments.

Reference now is made to FIG. 3, which is a simplified cross-section view of a semiconductor device after the substrate is formed, consistent with an illustrative embodiment. The semiconductor device can include a substrate 310, which can be a P-type or an N-type substrate.

In the illustrative example depicted in FIG. 3, the semiconductor device is depicted as being on silicon as the substrate 310, while it will be understood that other types as the substrate 310 may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the substrate 310 can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

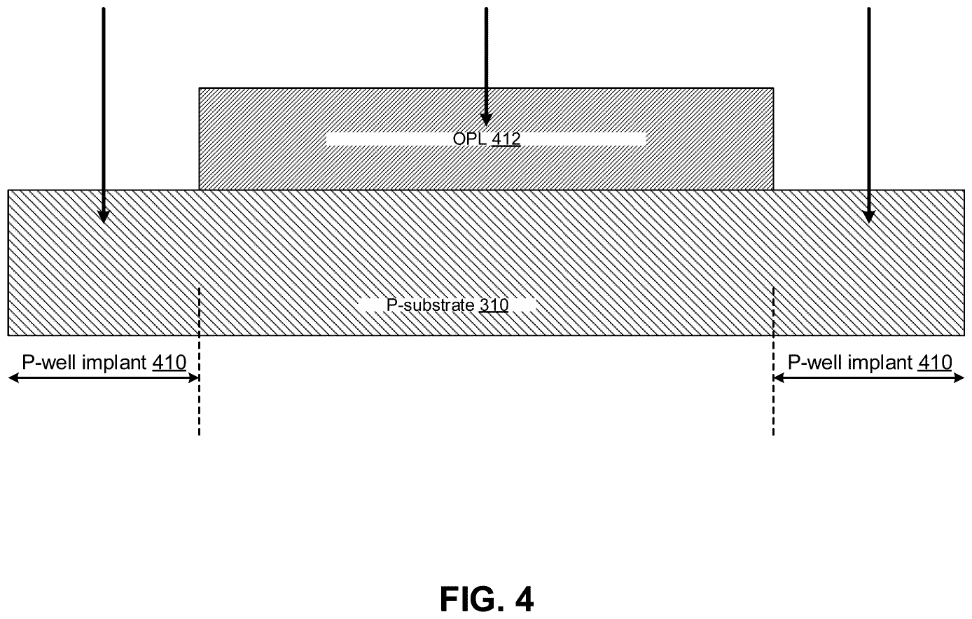

FIG. 4 illustrates a semiconductor device after the implantation of the substrate, according to some embodiments. In some embodiments, an organic planarization layer, OPL 412, is formed over portions of the substrate 310 to protect them from further processing. The OPL 412 can include a photo-sensitive organic polymer having a light-sensitive material that, when exposed to electromagnetic radiation, is chemically altered and thus configured to be removed using a developing solvent. For example, in some embodiments, the photo-sensitive organic polymer can be polyacrylate resin, epoxy resin, phenol resin, polyamide resin, polyimide resin, unsaturated polyester resin, polyphenylenether resin, polyphenylenesulfide resin, or benzocyclobutene. In some embodiments, the OPL 412 can include any organic polymer and a photoactive compound having a molecular structure that can attach to the molecular structure of the organic polymer. In some embodiments, the OPL 412 material is selected to be compatible with an overlying antireflective coating and/or an overlying photoresist. In some embodiments, the OPL 412 can be applied using spin coating technology, although other techniques are within the contemplated scope of the present disclosure. Subsequently, the exposed portions of the etch stop layer are removed.

Portions of the substrate that are not covered with OPL 412 are implanted with a suitable material to form P-well implant 410.

The implantation process for forming the P-well involves accelerating ions of the chosen P-type dopant to high energies and directing them into the substrate. Ion implantation allows for precise control over the dopant concentration and depth profile by adjusting parameters such as ion energy and dosage. The implanted ions penetrate the silicon lattice and come to rest at specific depths, creating a region with increased electron concentration. After implantation, the substrate can undergo an annealing process to heal damage to the crystal lattice caused by the high-energy ion bombardment and activates the dopants by allowing them to occupy substitutional sites within the silicon lattice.

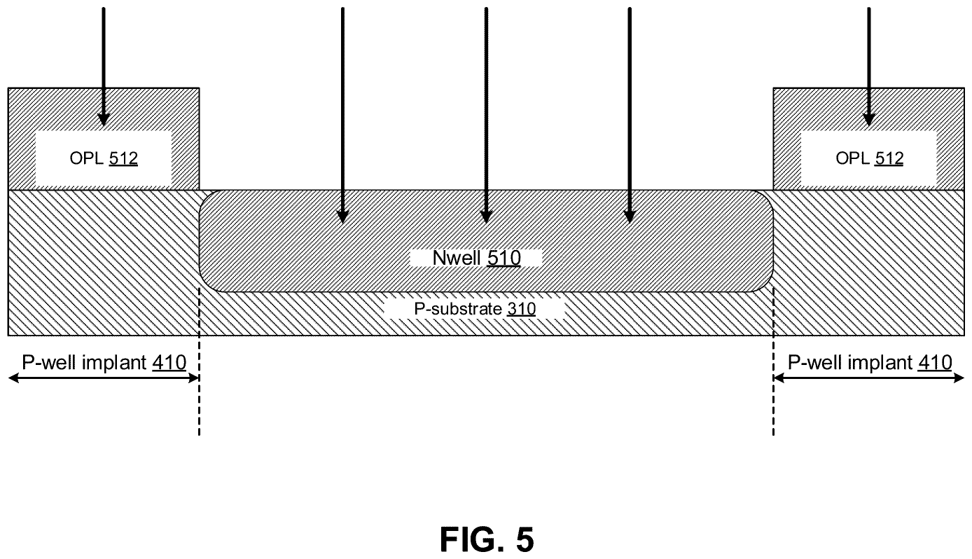

FIG. 5 illustrates a semiconductor device after the implantation of the substrate, according to some embodiments. In some embodiments, the OPL 412 is removed and an OPL 512 is formed over the P-well implant 410 to protect them from further processing. The process involves N-type patterning to form the base region of the semiconductor device. By applying a photosensitive resist and exposing it to a patterned light source, precise regions are delineated on the wafer, which allows for the selective introduction of dopants to create the desired electrical characteristics in specific areas. To form the N-well 510, e.g., the base, an N-type dopant is introduced into the designated region of the semiconductor substrate. N-type doping can involve adding impurities that have five valence electrons, such as phosphorus or arsenic. The extra electrons become free charge carriers within the silicon lattice, enhancing the material's conductivity.

The implantation process for forming the N-well involves accelerating ions of the chosen N-type dopant to high energies and directing them into the substrate. Ion implantation allows for precise control over the dopant concentration and depth profile by adjusting parameters such as ion energy and dosage. The implanted ions penetrate the silicon lattice and come to rest at specific depths, creating a region with increased electron concentration. After implantation, the substrate can undergo an annealing process to heal damage to the crystal lattice caused by the high-energy ion bombardment and activates the dopants by allowing them to occupy substitutional sites within the silicon lattice. The formation of the N-well establishes an N-type region that serves as the base in the bipolar junction transistor.

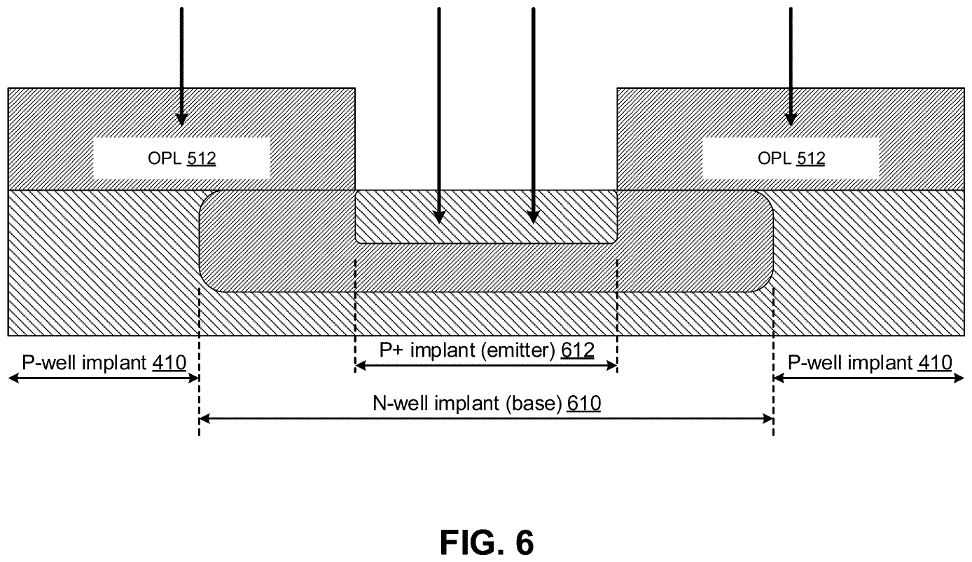

FIG. 6 illustrates a semiconductor device after the implantation of the emitter, according to some embodiments. In some embodiments, the P+implant (emitter) 612 is formed by implanting upper portions of the N-well 510. Thus, the P+implant (emitter) 612 is formed over the N-well 510 and the N-well implant (base) 610. The implanted substrate can serve as the collector.

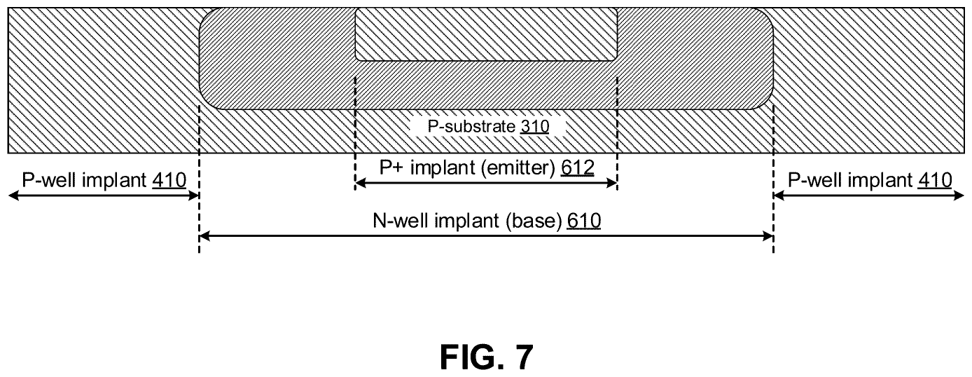

FIG. 7 illustrates a semiconductor device after the removal of the OPL, according to some embodiments. In some embodiments the OPL is removed from the semiconductor device.

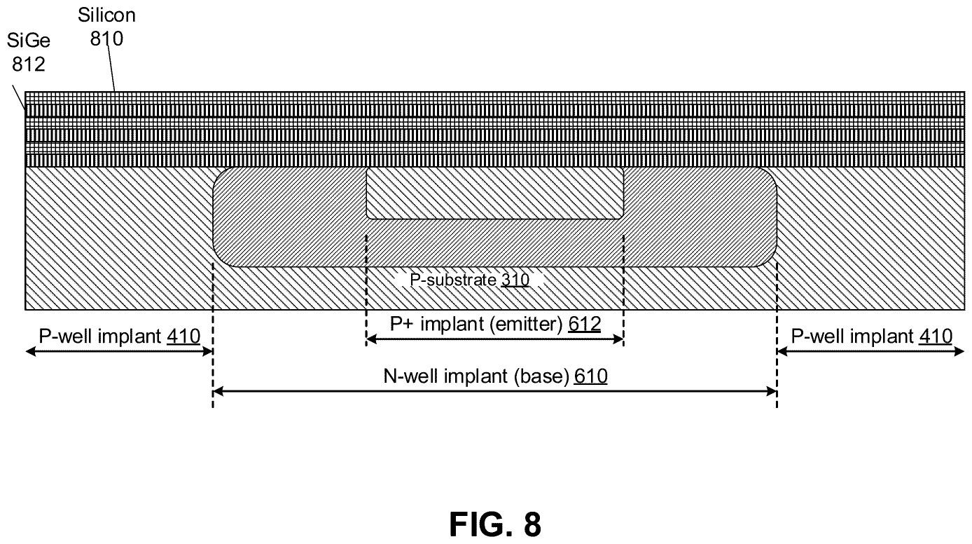

Reference now is made to FIG. 8, which is a simplified view of a semiconductor device after the formation of the nanosheet stack, consistent with an illustrative embodiment. In some embodiments, alternating layers of Si 810 and SiGe 812 are formed over the semiconductor device to form the nanosheet stacks. Afterwards, a layer of nitride can be formed over the semiconductor device.

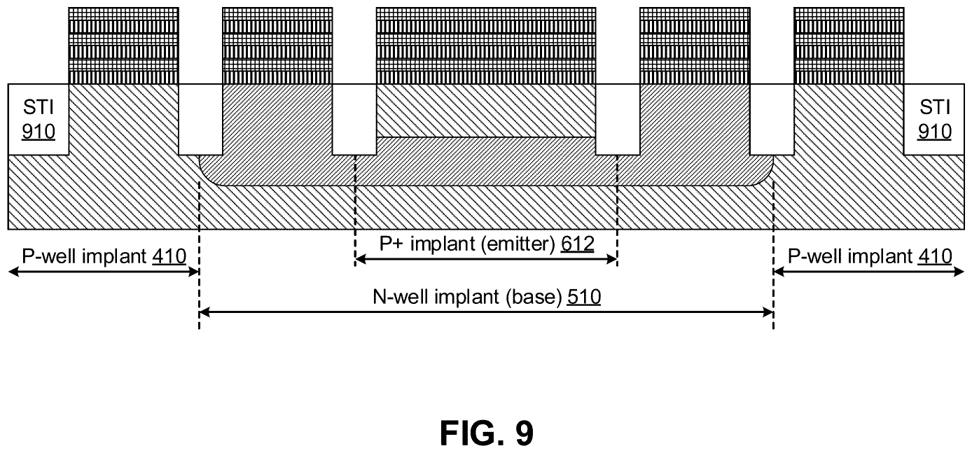

Reference now is made to FIG. 9, which is a simplified view of a semiconductor device after the patterning of the active areas, consistent with an illustrative embodiment. In some embodiments, an oxide layer is formed over the semiconductor device and then the semiconductor is patterned to form the nanosheet regions. Recesses are formed over the semiconductor device and STI 910 is formed in the recesses.

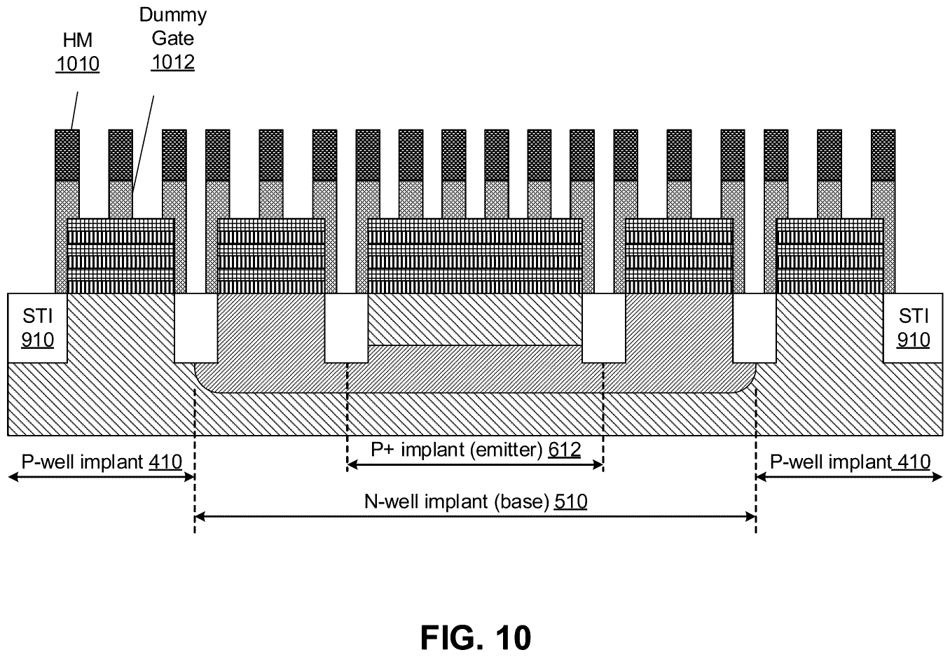

FIG. 10 illustrates a semiconductor device after the formation of dummy gates, according to some embodiments. In some embodiments, dummy gates 1012 are formed over the semiconductor device. The dummy gates 1012 can be made of polysilicon and/or amorphous silicon. A layer of dummy oxide can be formed prior to the formation of the dummy gates 1012. Hard masks, HM 1010, are formed over the dummy gates 1012.

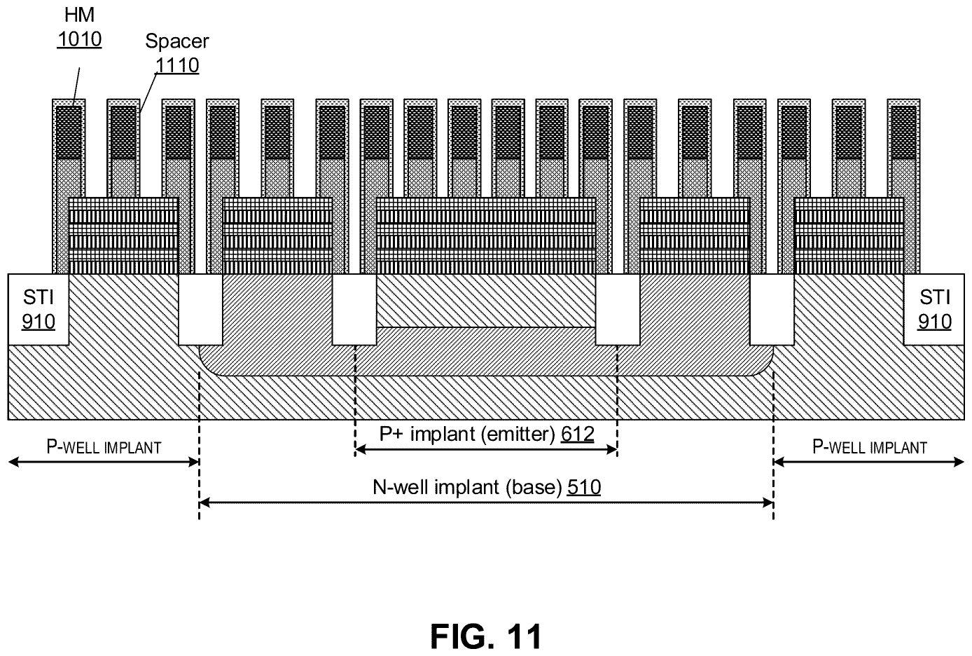

Reference now is made to FIG. 11, which is a simplified cross-section view of a semiconductor device after the formation of spacer, consistent with an illustrative embodiment. In some embodiments, a spacer 1110 is formed over the semiconductor device.

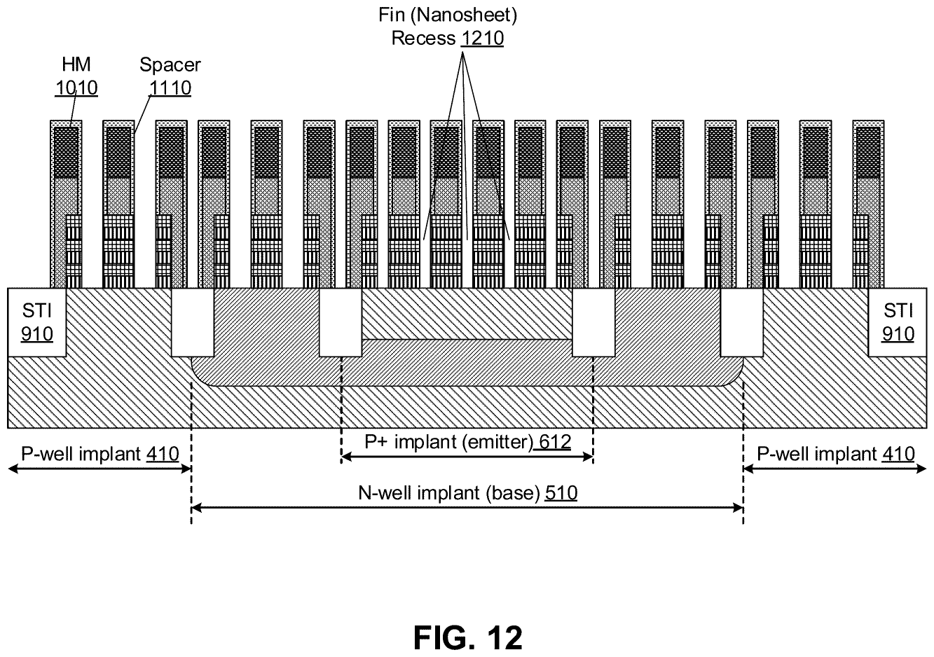

Reference now is made to FIG. 12, which is a simplified cross-section view of a semiconductor device, after the recession of the stacks, consistent with an illustrative embodiment. In some embodiments, portions of the spacer 1110 are removed and the stacks are recessed to form nanosheet recesses 1210. The portions of the spacer 1110 can be removed by a reactive ion etching (RIE) process. A reactive ion etching (RIE) technique can be performed. Generally, RIE is a dry etching process used in semiconductor device fabrication to remove materials from the surface of a substrate selectively. In some embodiments, RIE can involve the use of reactive ions and plasma to react with and remove specific materials chemically. In an embodiment, the RIE process begins by placing the semiconductor device inside a vacuum chamber. The chamber is then evacuated to create a low-pressure environment. Reactive gases, which can include a combination of a chemically reactive gas and an inert gas, are introduced into the chamber. The chemically reactive gas, such as fluorine-based gases (e.g., CF4, SF6) or chlorine-based gases (e.g., Cl2), can react with the material to be etched, i.e., the second substrate, Si, while the inert gas, e.g., argon, can help to control the ion bombardment.

In some embodiments, radiofrequency or microwave power is applied to create a plasma within the chamber. In such embodiments, power excites the gas molecules, causing them to ionize and form a plasma of reactive ions and electrons. The plasma can include reactive ions that chemically react with the silicon. The reactive ions bombard the substrate surface, break chemical bonds and remove silicon. In various embodiments, the RIE process can be selective, meaning it can mainly affect the target material, i.e., silicon, while leaving other materials, such as masking layers or underlying layers, relatively unaffected.

In some embodiments, to achieve selective etching, an etch mask can be applied on the substrate surface prior to the RIE process. The etch mask protects certain regions from etching, allowing the reactive ions to remove the exposed material selectively. The etching process can be controlled to achieve specific etch profiles, such as vertical sidewalls or tapered structures. Parameters such as gas composition, pressure, power, and process duration are adjusted to achieve the desired etch characteristics. In some embodiments, endpoint detection techniques, such as optical emission spectroscopy or laser interferometry, can be used to determine when the etching process has reached a desired endpoint. This ensures accurate control of the etch depth and prevents over-etching. After the etching process is completed, the substrate can be cleaned to remove any residue or by-products from the etching. Cleaning can involve rinsing with solvents or plasma cleaning to ensure the substrate's surface is free from contaminants.

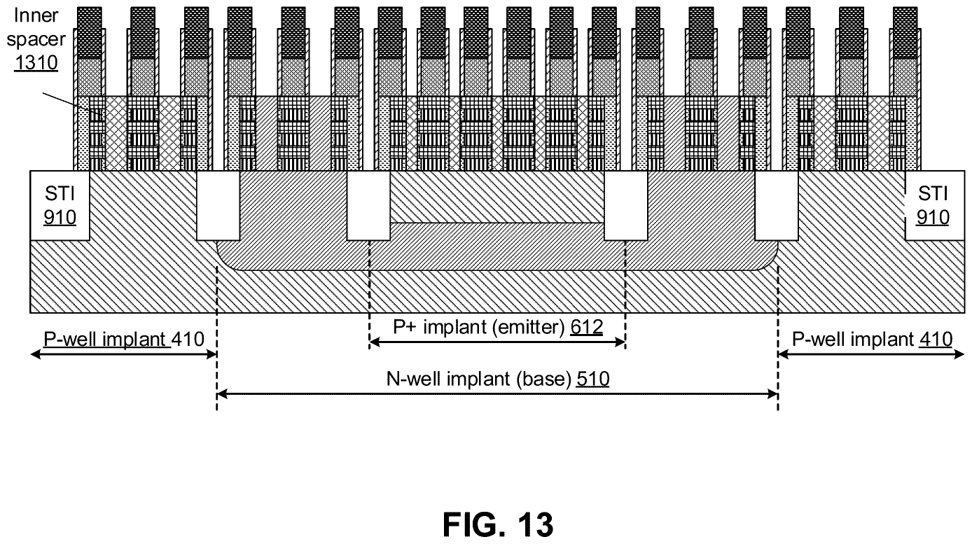

FIG. 13 illustrates a semiconductor device after the formation of inner spacer, according to some embodiments. In some embodiments, inner spacer 1310 is formed over the alternating layers of silicon and silicon germanium.

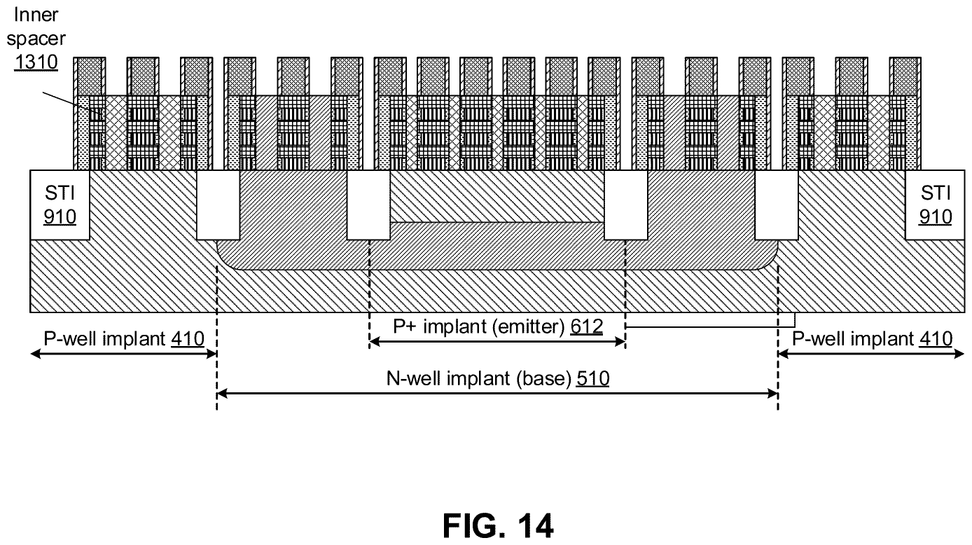

FIG. 14 illustrates a semiconductor device after removal of the gate hard masks, according to some embodiments. In some embodiments, the dummy gates and the hard masks are removed.

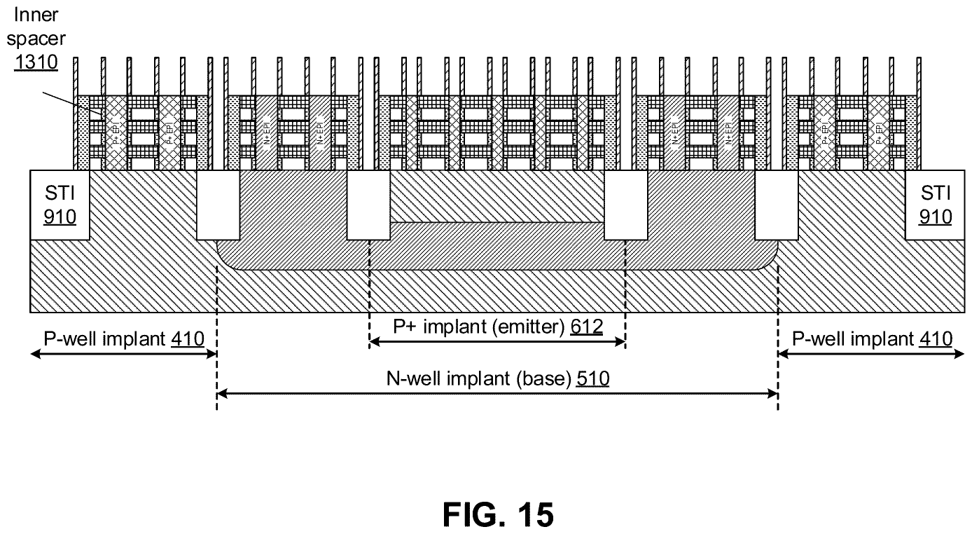

FIG. 15 illustrates a semiconductor device after the release of the channels, in accordance with some embodiments. In some embodiments, the silicon germanium is removed.

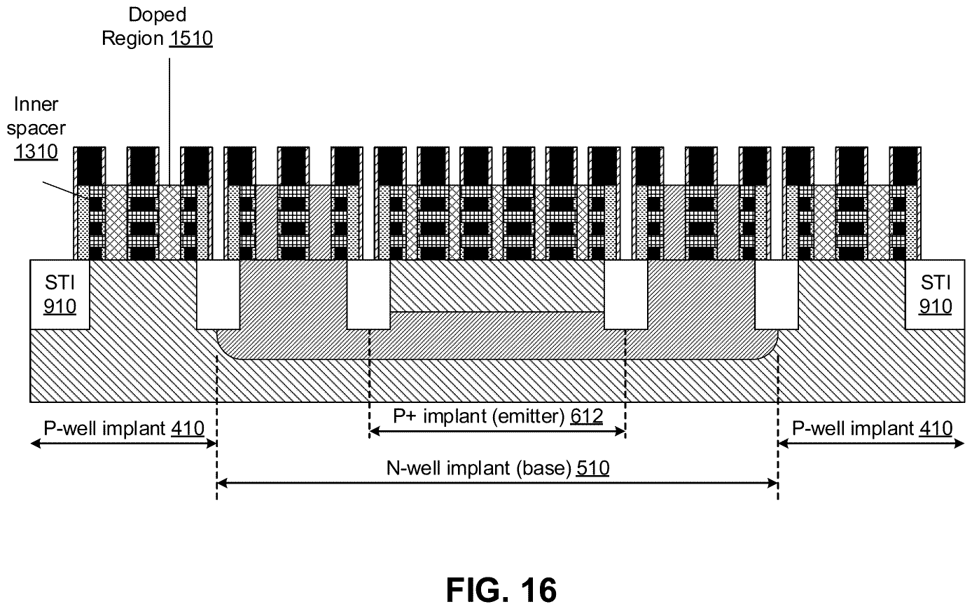

FIG. 16 illustrates a semiconductor device after the replacement of the gate with metal, consistent with an illustrative embodiment. In some embodiments, the source/drain regions, e.g., doped regions 1510, are formed over the semiconductor device. The gates are replaced with metals.

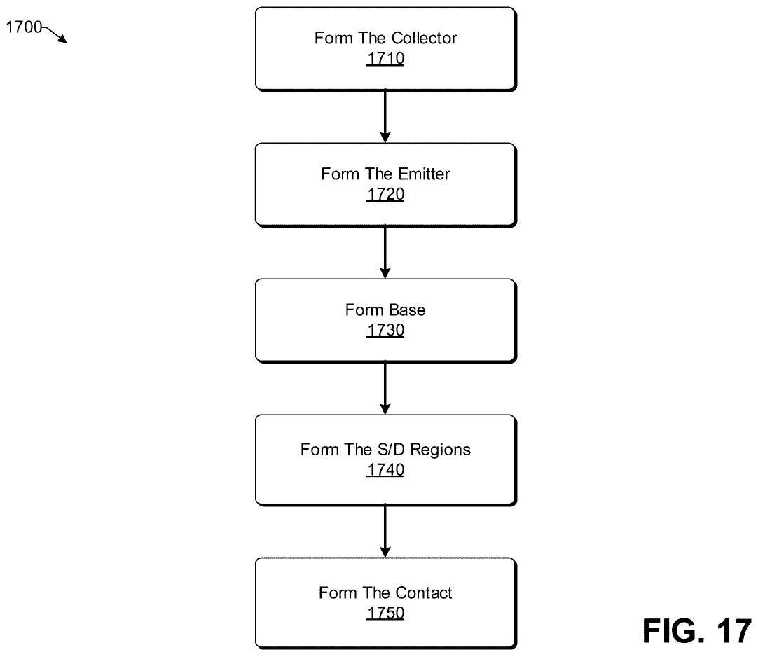

FIG. 17 illustrates a block diagram of a method 1700 for forming the semiconductor device, in accordance with some embodiments. As shown by block 1710, a collector is formed.

As shown by block 1720, an emitter is formed.

As shown by block 1730, a base is formed.

As shown by block 1740, the doped regions are formed.

As shown by block 1750, the contact is formed.

It should be noted that, the order of formation of the emitter, the base, and the collector, can be interchangeable.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a vertical bipolar junction device, comprising:
a collector;
a base over the collector;
an emitter over the base;
one or more source/drain region and dummy gate alternatively and laterally extended over the emitter; and
a contact over source/drain regions of the one or more source/drain region and dummy gate.

2. The semiconductor device of claim 1, wherein:
the emitter, the one or more alternating source/drain region/dummy gate; and
the contact over each source/drain regions of the one or more alternating source/drain region/dummy gate form an ohmic contact.

3. The semiconductor device of claim 1, wherein:
the emitter, the base and the collector are doped with an N-type dopant or a P-type dopant; and
a concentration of a dopant of the emitter is higher than a concentration of a dopant of the collector and a concentration of a dopant of the base.

4. The semiconductor device of claim 3, wherein the dopant of the emitter is at least one of: B, BF2, or a P-type dopant.

5. The semiconductor device of claim 1, wherein the vertical bipolar junction device is a P-type-/N-type/P-type device.

6. The semiconductor device of claim 1, further comprising a plurality of P-type field-effect transistors (PFET) dummy gates over the emitter.

7. The semiconductor device of claim 1, further comprising a plurality of N-type field-effect transistors (NFET) dummy gates over the base.

8. The semiconductor device of claim 1, further comprising a plurality of P-type field-effect transistors (PFET) dummy gates over the collector.

9. A method of fabricating a semiconductor device, the method comprising:
forming a vertical bipolar junction device, comprising:
forming a collector;
forming a base over the collector;
forming an emitter over the base;
forming one or more source/drain region and dummy gate alternatively and laterally extended over the emitter; and
forming a contact over source/drain regions of the one or more source/drain region and dummy gate.

10. The method of claim 9, further comprising forming an ohmic contact by the emitter, the one or more alternating source/drain region/dummy gate, and the contact over each source/drain regions of the one or more alternating source/drain region/dummy gate.

11. The method of claim 9, further comprising doping the emitter, the base and the collector with an N-type dopant or a P-type dopant, wherein a concentration of a dopant of the emitter is higher than a concentration of a dopant of the collector and a concentration of a dopant of the base.

12. The method of claim 11, wherein the dopant of the emitter is at least one of: B, BF2, or a P-type dopant.

13. The method of claim 9, wherein the vertical bipolar junction device is a P-type-/N-type/P-type device.

14. The method of claim 9, further comprising forming a plurality of P-type field-effect transistors (PFET) dummy gates over the emitter.

15. The method of claim 9, further comprising forming a plurality of N-type field-effect transistors (NFET) dummy gates over the base.

16. The method of claim 9, further comprising forming a plurality of P-type field-effect transistors (PFET) dummy gates over the collector.

17. A semiconductor device, comprising:
a vertical bipolar junction device, comprising:
a collector;
a base over the collector; and
an emitter over the base, wherein:
the emitter, the base and the collector are doped with an N-type dopant or a P-type dopant; and
a concentration of a dopant of the emitter is higher than a concentration of a dopant of the collector and a concentration of a dopant of the base.

18. The semiconductor device of claim 17, further comprising:
one or more alternating source/drain region/dummy gate laterally extended over the emitter; and
a contact over each source/drain regions of the one or more alternating source/drain region/dummy gate.

19. The semiconductor device of claim 18, wherein the emitter, the one or more alternating source/drain region/dummy gate, and the contact over each source/drain regions of the one or more alternating source/drain region/dummy gate form an ohmic contact.

20. The semiconductor device of claim 17, further comprising:
a plurality of P-type field-effect transistors (PFET) dummy gates over the emitter;
a plurality of N-type field-effect transistors (NFET) dummy gates over the base; and
a plurality of P-type field-effect transistors (PFET) dummy gates over the collector.
